(19) United States
(12) Patent Application Publication
(10) Pub. No.: US 2025/0022395 A1
(43) Pub. Date: Jan. 16, 2025

(54) INSPECTING METHOD OF DISPLAY PANEL AND INSPECTING DEVICE PERFORMING THE SAME

(71) Applicant: Samsung Display Co., LTD., Yongin-si (KR)

(72) Inventors: Ji Won CHA, Yongin-si (KR); Don Hyeong KIM, Yongin-si (KR); Gyung Su LIM, Yongin-si (KR); Hyung Tae JUNG, Yongin-si (KR)

(21) Appl. No.: 18/631,212

(22) Filed: Apr. 10, 2024

(30) Foreign Application Priority Data
Jul. 10, 2023 (KR) 10-2023-0089385

(51) Int. Cl. G09G 3/00

(52) U.S. Cl. CPC G09G 3/006; G09G 2320/043; G09G 2330/12

(57) ABSTRACT

An inspecting method of a display panel includes training an artificial intelligence model based on age data of a test display panel for an aging characteristic; generating virtual age data of a virtual display panel from the aging characteristic using the artificial intelligence model; and predicting an age of the display panel based on the virtual age data.

This application claims priority to Korean Patent Application No. 10-2023-0089385, filed on Jul. 10, 2023, and all the benefits accruing therefrom under 35 U.S.C. § 119, the content of which in its entirety is herein incorporated by reference.

### BACKGROUND OF THE INVENTION

### (a) Field

The disclosure relates to an inspecting method of a display panel and an inspecting device performing the same. More specifically, the disclosure relates to an inspecting method of a display panel that predicts an age of the display panel and an inspecting device performing the same.

### (b) Description of the Related Art

As information technology has developed, importance of a display device, which is a connection medium between a user and information, has been highlighted. Accordingly, the use of display devices such as a liquid crystal display device, an organic light-emitting display device, or the like has been increasing.

A display panel includes a plurality of sub-pixels that receive electrical signals to emit light in order to display an image to the outside. Each sub-pixel includes a light-emitting element, and the light-emitting element may be aged as usage thereof increases. In addition, the characteristics of the light-emitting element may be changed due to the aging. In an embodiment, the luminescence characteristics of the light-emitting element may change over time. Therefore, various studies have been attempted to predict the age of the light-emitting element (that is, the age of the display panel) according to the aging time of the light-emitting element.

### SUMMARY OF THE INVENTION

One feature of the disclosure is to provide an inspecting method of a display panel that may predict an age of the display panel by an artificial intelligence model.

Another feature of the disclosure is to provide an inspecting device that performs an inspecting method of a display panel.

An embodiment of the disclosure provides an inspecting method of a display panel. The method includes training an artificial intelligence model based on age data of a test display panel for aging characteristics; generating virtual age data of a virtual display panel from the aging characteristics using the artificial intelligence model; and predicting an age of the display panel based on the virtual age data.

In an embodiment, the age data of the test display panel may be a luminance retention rate according to an aging time of the test display panel.

In an embodiment, the artificial intelligence model may include a first artificial intelligence model according to a first aging time and a second artificial intelligence model according to a second aging time different from the first aging time.

In an embodiment, the aging characteristic may include at least one of an aging color, an aging grayscale, an initial aging luminance, an observation color, an observation grayscale, an initial observation luminance, an aging position, and a temperature.

In an embodiment, the training the artificial intelligence model may include displaying the aging color and the aging grayscale on a pattern of the test display panel; measuring the initial aging luminance of the pattern; displaying the observation color and the observation grayscale on the test display panel; measuring the initial observation luminance of the pattern; measuring the temperature of the test display panel; determining the age data of the test display panel; labeling the aging characteristic with the age data of the test display panel; and training the artificial intelligence model with the aging characteristic labeled with the age data of the test display panel.

In an embodiment, the age data of the test display panel may be measured by displaying the observation color and the observation grayscale on the test display panel.

In an embodiment, the age data of the test display panel may be measured according to an aging time for which the aging color and the aging grayscale are displayed.

In an embodiment, the aging characteristic may include at least one of an aging color, an aging grayscale, an initial aging luminance, an observation color, an observation grayscale, an initial observation luminance, an aging position, a temperature, an aging current, an observation current, and a light efficiency.

In an embodiment, the training the artificial intelligence model may include displaying the aging color and the aging grayscale on a pattern of the test display panel; measuring the initial aging luminance and the aging current of the pattern; displaying the observation color and the observation grayscale on the test display panel; measuring the initial observation luminance and the observation current of the pattern; measuring the temperature of the test display panel; determining the age data of the test display panel; labeling the aging characteristic with the age data of the test display panel; and training the artificial intelligence model with the aging characteristic labeled with the age data of the test display panel.

In an embodiment, the artificial intelligence model may be a regression model.

In an embodiment, the artificial intelligence model may be one of a random forest regression model, an extra tree regression model, and a gradient boosting regression model.

In an embodiment, the artificial intelligence model may be generated by blending at least two regression models.

In an embodiment, the predicting the age of the display panel may include normalizing the virtual age data and generating normal distribution data; and predicting the age of the display panel based on data corresponding to a predetermined ratio of the normal distribution data.

In an embodiment, the predicting the age of the display panel may include normalizing the virtual age data and the age data of the test display panel and generating normal distribution data; and predicting the age of the display panel based on data corresponding to a predetermined ratio of the normal distribution data.

Another embodiment of the disclosure provides an inspecting device including: a memory which stores an artificial intelligence model; and a processor which predicts an age of a display panel by the artificial intelligence model stored in the memory; wherein the processor generates virtual age data of a virtual display panel from an aging characteristic by the artificial intelligence model and predicts the age of the display panel based on the virtual age data, and the artificial intelligence model is trained based on age data of a test display panel for the aging characteristic.

In an embodiment, the artificial intelligence model may include a first artificial intelligence model according to a first aging time and a second artificial intelligence model according to a second aging time different from the first aging time.

In an embodiment, the aging characteristic may include at least one of an aging color, an aging grayscale, an initial aging luminance, an observation color, an observation grayscale, an initial observation luminance, and a temperature.

In an embodiment, the aging characteristic may include at least one of an aging color, an aging grayscale, an initial aging luminance, an observation color, an observation grayscale, an initial observation luminance, a temperature, an aging current, an observation current, and a light efficiency.

In an embodiment, the artificial intelligence model may be a regression model.

In an embodiment, the artificial intelligence model may be generated by blending at least two regression models.

According to the inspecting method of the display panel in the embodiments of the disclosure, by generating virtual age data of a virtual display panel by an artificial intelligence model, it is possible to improve the accuracy of age prediction even with a relatively small number of inspection display panels.

However, the effects of the disclosure are not limited to the above-described effects, and may be variously extended without departing from the spirit and scope of the disclosure.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 illustrates an embodiment of a flowchart of an inspecting method of a display panel according to the disclosure.

FIG. 2 illustrates a block diagram of a display device according to the inspecting method of the display panel of FIG. 1.

FIG. 3 illustrates an embodiment of a display area of a test display panel according to the inspecting method of the display panel of FIG. 1.

FIG. 4 illustrates an embodiment of observation color and observation grayscale according to the inspecting method of the display panel of FIG. 1.

FIG. 5 is a drawing for explaining age data.

FIG. 6 and FIG. 7 illustrate an embodiment of age data according to the inspecting method of the display panel of FIG. 1.

FIG. 8 illustrates a block diagram of an embodiment of an artificial intelligence model according to the inspecting method of the display panel of FIG. 1.

FIG. 9 illustrates an embodiment of age data of a first test display panel according to the inspecting method of the display panel in embodiments of the disclosure.

FIG. 10 illustrates a table of an embodiment of a coefficient of determination of an artificial intelligence model according to the inspecting method of the display panel of FIG. 1.

FIG. 11 illustrates a graph of an embodiment of normal distribution data according to the inspecting method of the display panel of FIG. 1.

FIG. 12 illustrates a graph of an embodiment of normal distribution data according to an inspecting method of a display panel according to the disclosure.

FIG. 13 illustrates a block diagram of an inspecting device in embodiments of the disclosure.

### DETAILED DESCRIPTION

Hereinafter, embodiments of the disclosure will be described in detail with reference to the accompanying drawings. The following description is intended to provide only a sufficient disclosure to enable the understanding of the operation of the invention, and any other disclosure is omitted to avoid obscuring the scope of the invention. In addition, the inventive concept may be embodied in different forms and is not limited to the embodiments set forth herein. The embodiments described herein are provided for the purpose of describing the technical concept of the invention in sufficient detail for those skilled in the art to easily practice it.

Throughout the specification, when it is described that an element is “connected” to another element, this includes not only being “directly connected”, but also being “indirectly connected” with another device in between. The terms used herein are for the purpose of describing specific embodiments and are not intended to limit the scope of the invention. Throughout the specification, unless explicitly described to the contrary, the word “comprise” and variations such as “comprises” or “comprising” will be understood to imply the inclusion of stated elements but not the exclusion of any other elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms first, second, etc. may be used herein to describe various constituent elements, these constituent elements should not be limited by these terms. These terms are used to distinguish one constituent element from another constituent element. Thus, a first constituent element discussed below could be termed a second constituent element without departing from the teachings of the disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (for example, rotated 90 degrees or at other orientations), and, as such, the spatially relative descriptors used herein interpreted accordingly.

Various embodiments are described herein with reference to cross-sectional illustrations that are schematic illustrations of idealized embodiments. As such, variations from the shapes of the illustrations as a result, for example, of manufacturing techniques and/or tolerances, are to be expected. Thus, embodiments disclosed herein should not be construed as limited to the particular illustrated shapes of regions, but are to include deviations in shapes that result from, for instance, manufacturing. Thus, the regions illustrated in the drawings are schematic in nature and their shapes are not intended to illustrate the actual shape of a region of a device and are not intended to be limiting.

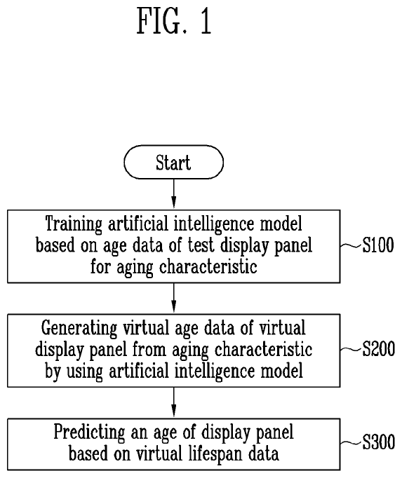

FIG. 1 illustrates a flowchart of an embodiment of an inspecting method of a display panel according to the disclosure.

Referring to FIG. 1, the inspecting method of the display panel in FIG. 1 may include training an artificial intelligence model based on age data of a test display panel for aging characteristics (S100), generating virtual age data of a virtual display panel from the aging characteristics using the artificial intelligence model (S200), and predicting an age of the display panel based on the virtual age data (S300)

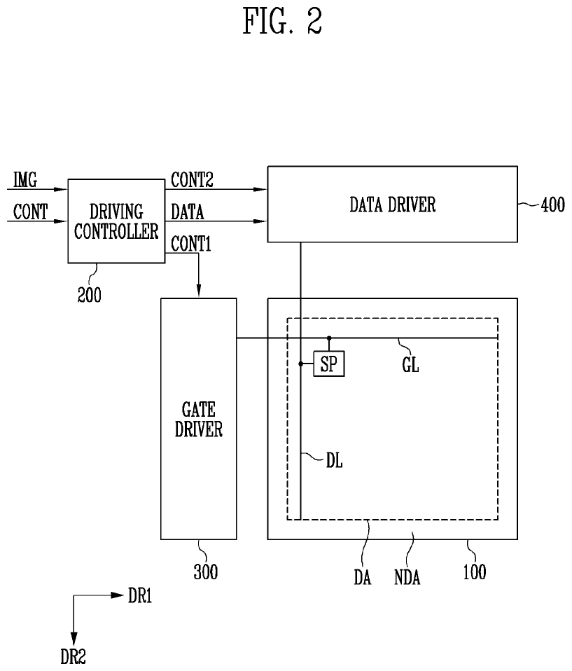

Hereinafter, this will be described in detail with reference to FIG. 2 to FIG. 13.

FIG. 2 illustrates a block diagram of a display device according to the inspecting method of the display panel of FIG. 1.

Referring to FIG. 2, the display device may include a display panel 100, a driving controller 200, a gate driver 300, and a data driver 400. In the embodiment, the driving controller 200 and data driver 400 may be integrated on a single chip.

The display panel 100 may include a display area DA displaying an image and a non-display area NDA disposed adjacent to the display area DA. In the embodiment, the gate driver 300 may be disposed (e.g., mounted) in the non-display area NDA.

The display panel 100 may include a plurality of gate lines GL, a plurality of data lines DL, and a plurality of sub-pixels SP electrically connected to the gate lines GL and the data lines DL. The gate lines GL may be extended in a first direction DR1, and the data lines DL may be extended in a second direction DR2 crossing the first direction DR1.

The driving controller 200 may receive input image data IMG and input control signal CONT from a processor (e.g., a graphics processing unit (“GPU”) or the like). In an embodiment, the input image data IMG may include red image data, green image data, and blue image data, for example. In the embodiment, the input image data IMG may further include white image data. In another embodiment, the input image data IMG may include magenta image data, yellow image data, and cyan image data. The input control signal CONT may include a master clock signal and a data enable signal. The input control signal CONT may further include a vertical synchronization signal and a horizontal synchronization signal.

The driving controller 200 may generate a first control signal CONT1, a second control signal CONT2, and a data signal DATA based on the input image data IMG and the input control signal CONT.

The driving controller 200 may generate the first control signal CONT1 for controlling the operation of the gate driver 300 based on the input control signal CONT to output it to the gate driver 300. The first control signal CONT1 may include a vertical start signal and a gate clock signal.

The driving controller 200 may generate the second control signal CONT2 for controlling the operation of the data driver 400 based on the input control signal CONT to output it to the data driver 400. The second control signal CONT2 may include a horizontal start signal and a load signal.

The driving controller 200 may receive the input image data IMG and the input control signal CONT to generate the data signal DATA. The driving controller 200 may output the data signal DATA to the data driver 400.

The gate driver 300 may generate gate signals for driving the gate lines GL in response to the first control signal CONT1 received from the driving controller 200. The gate driver 300 may output the gate signals to the gate lines GL. In an embodiment, the gate driver 300 may sequentially output the gate signals to the gate lines GL, for example.

The data driver 400 may receive the second control signal CONT2 and the data signal DATA from the driving controller 200. The data driver 400 may generate data voltages obtained by converting the data signal DATA into an analog voltage. The data driver 400 may output the data voltages to the data line DL.

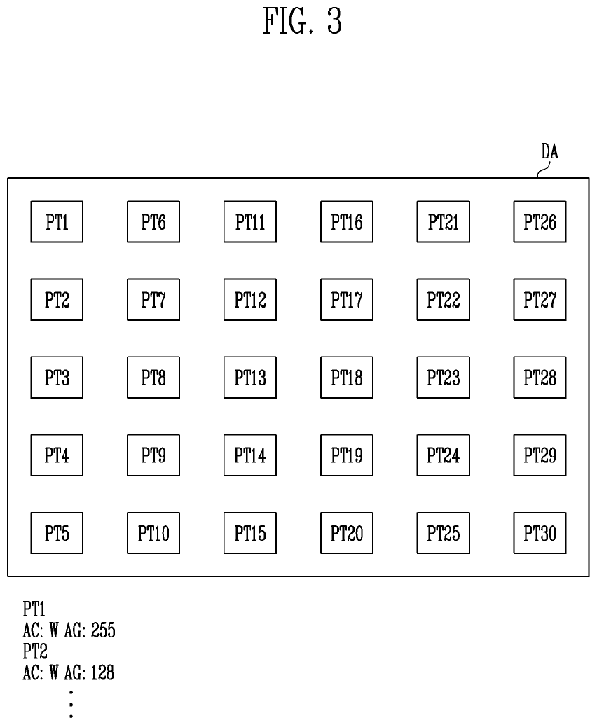

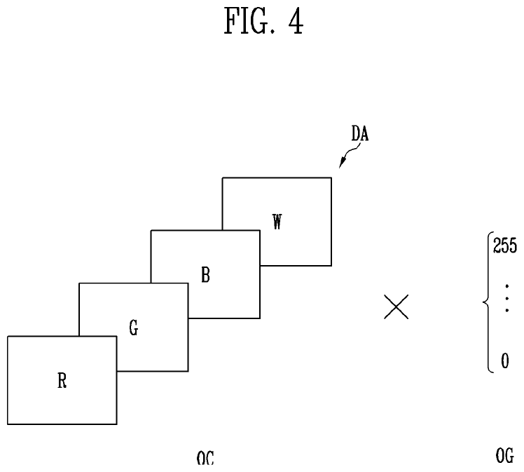

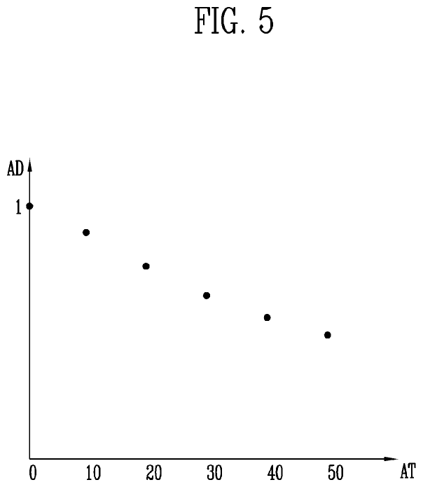

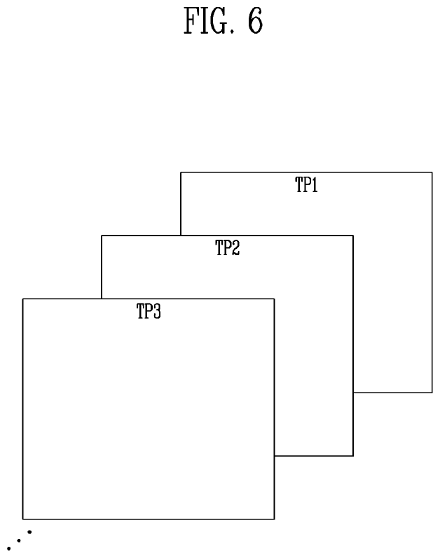

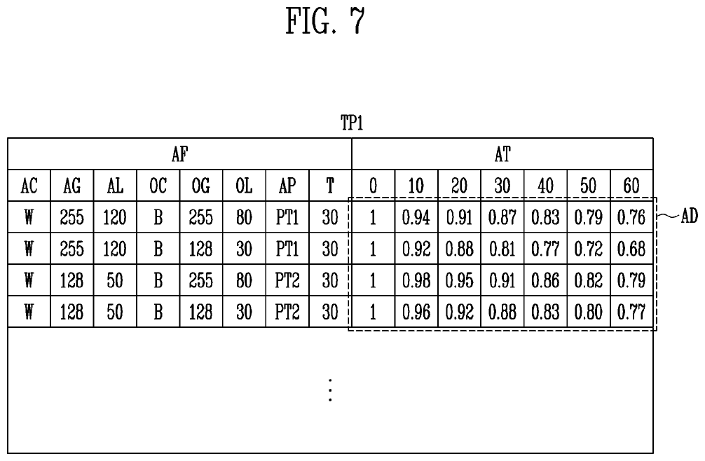

FIG. 3 illustrates an embodiment of a display area of a test display panel according to the inspecting method of the display panel of FIG. 1, FIG. 4 illustrates an embodiment of observation color and observation grayscale according to the inspecting method of the display panel of FIG. 1, FIG. 5 is a drawing for explaining age data, and FIG. 6 and FIG. 7 illustrate an embodiment of age data according to the inspecting method of the display panel of FIG. 1.

For better comprehension and ease of description, aging time (AT) in FIG. 5 and FIG. 7 and initial aging luminance (AL), initial observation luminance (OL), and temperature (T) in FIG. 7 represent relative values.

Referring to FIG. 3 to FIG. 7, the inspecting method of the display panel of FIG. 1 may display aging colors AC and aging grayscales AG on patterns PT1 to PT30 of test display panels TP1 to TP3, may measure aging luminance of the patterns PT1 to PT30, may display observation colors OC and observation grayscales OG on the test display panels TP1 to TP3, may measure observation luminance of the patterns PT1 to PT30, may measure temperatures T of the test display panels TP1 to TP3, may determine age data AD of the test display panels TP1 to TP3, may label aging characteristics with the age data AD of the test display panels TP1 to TP3, and may train an artificial intelligence model based on the aging characteristics labeled with the age data AD of the test display panels TP1 to TP3.

The inspecting method of the display panel of FIG. 1 may display images (hereinafter, also referred to as aging images) having the aging colors AC and the aging grayscales AG on the patterns PT1 to PT30 of the test display panels TP1 to TP3 to age the test display panels TP1 to TP3. In addition, the inspecting method of the display panel of FIG. 1 may measure the observation luminance by displaying an image (hereinafter, also referred to as an observation image) with the observation color OC and the observation grayscale OG on the test display panels TP1 to TP3 aged by the aged image. In the embodiment, the aging image may have a different color and grayscale in the respective patterns PT1 to PT30, and the observation image may have the same color and grayscale in the respective patterns PT1 to PT30. That is, the aging luminance of each of the patterns PT1 to PT30 may be luminance of each of the patterns PT1 to PT30 when the aging image is displayed, and the observation luminance may be luminance of each of the patterns PT1 to PT30 when the observation image is displayed.

Here, the aging image may be an image for aging each of the patterns PT1 to PT30, and the observation image may be an image for measuring the characteristic change (that, the age data AD) according to the aging time AT in a predetermined color (that is, the observation color OC) and a predetermined grayscale (that is, the observation grayscale OG). That is, since the respective patterns PT1 to PT30 are aged with an aging image having various aging colors AC and aging grayscales AG, observation luminance of an observation image displaying the same color and grayscale in all patterns PT1 to PT30 may vary in the respective patterns PT1 to PT30. However, the disclosure is not limited to the observation image having the same color and grayscale in all patterns PT1 to PT30.

The aging time AT may be a time when an aging image is displayed. In an embodiment, the age data AD when the aging time AT is 10 may be the age data AD when the displayed time of the aging image is 10, for example. A detailed description of the age data AD will be described later.

Initial aging luminance AL and initial observation luminance OL may be reference luminance for determining the age data AD. A detailed description of this will be described later.

In the embodiment, the initial aging luminance AL may be the aging luminance of the patterns PT1 to PT30 measured by displaying the aging images on the patterns PT1 to PT30 of the test display panels TP1 to TP3 when the aging time AT is 0.

In another embodiment, the initial aging luminance AL may be the aging luminance of the patterns PT1 to PT30 measured by displaying the aging images on the patterns PT1 to PT30 of the test display panels TP1 to TP3, and the aging luminance of patterns (PT1 to PT30) after the patterns PT1 to PT30 of the test display panels TP1 to TP3 are aged for a predetermined period of time by the aging images. In this case, the aging time AT may be a time obtained by subtracting the predetermined time from the time when the aging image is displayed. That is, when the aging image is displayed for the predetermined time, the aging time AT may be zero.

In the embodiment, the initial observation luminance OL may be the observation luminance of the patterns PT1 to PT30 measured by displaying the observation images on the test display panels TP1 to TP3 when the aging time AT is 0.

In another embodiment, the initial observation luminance OL may be the observation luminance of the patterns PT1 to PT30 measured by displaying the observation images on the test display panels TP1 to TP3 after the test display panels TP1 to TP3 aged for a predetermined period of time by the aging images. In this case, the aging time AT may be a time obtained by subtracting the predetermined time from the time when the aging image is displayed. That is, when the aging image is displayed for the predetermined time, the aging time AT may be zero.

The age data AD of the test display panels TP1 to TP3 may be measured by displaying the observation color OC and the observation grayscale OG on the test display panel.

The age data AD of the test display panels TP1 to TP3 may be a luminance retention rate according to the aging time AT of the test display panels TP1 to TP3. Here, the luminance retention rate may be a ratio of luminance when the aging time AT is zero (that is, the initial observation luminance OL) and the observation luminance when aged by the aging time AT. In an embodiment, as shown in FIG. 5, the age data AD when the aging time AT is 0 may be 1, for example.

In an embodiment, the aging characteristic may include at least one of an aging color AC, an aging grayscale AG, an initial aging luminance AL, an observation color OC, an observation grayscale OG, an initial observation luminance OL, an aging position AP (e.g., positions of the patterns PT1 to PT30), and a temperature T, for example. However, the disclosure is not limited to the elements included in the aging characteristic.

Here, the aging luminance and the observation luminance are measured by a luminance meter, the temperature T is measured by a temperature meter, and the temperature T may be a temperature of the test display panel. That is, even when the aging color AC, the aging grayscale AG, the observation color OC, the observation grayscale OG, and the aging position AP are the same, the initial aging luminance AL, the initial observation luminance OL, and the temperature T may be differently measured depending on the test display panel.

In the illustrated embodiment, thirty patterns PT1 to PT30 are illustrated, but the disclosure is not limited to the number of the patterns PT1 to PT30.

Referring to FIG. 3, the inspecting method of the display panel of FIG. 1 may display the aging color AC and the aging grayscale AG in the patterns PT1 to PT30 of the test display panels TP1 to TP3.

The test display panel may be a display panel for generating age data used for training of an artificial intelligence model. In addition, the display panel whose age is predicted does not necessarily have to be different from the test display panel. In an embodiment, a display panel whose age is predicted may be used as a test display panel, for example.

The test display panel may be aged by displaying the aging color AC and aging grayscale AG for each of the patterns PT1 to PT30. In addition, the aging colors AC and the aging grayscale AG of the respective patterns PT1 to PT30 may differ. Accordingly, the respective patterns PT1 to PT30 of the test display panel may be differently aged. Therefore, the age data AD of the test display panel described later may differ for the respective patterns PT1 to PT30.

In an embodiment, white (W) of 255 grayscales may be displayed on the first pattern PT1, for example. In an embodiment, white (W) of 128 grayscales may be displayed on the second pattern PT2, for example. However, the disclosure is not limited to the color and the grayscale displayed in each of the patterns PT1 to PT30.

Referring to FIG. 3 to FIG. 5, the age data AD of the test display panel may be measured according to the aging time AT in which the aging color AC and the aging grayscale AG are displayed.

In an embodiment, one of a red color R, a green color G, a blue color B, and a white color W may be displayed on the test display panel. In an embodiment, one of 0 to 255 grayscales may be displayed on the test display panel, for example. However, the disclosure is not limited to the color and grayscale displayed on the test display panel.

The light-emitting element of the sub-pixel may be aged as usage increases. In addition, due to the aging, the luminescence characteristics of the light-emitting element may be changed (e.g., luminance may decrease). That is, the age data AD may decrease as the aging time AT increases.

The aging time AT may be a time when the aging color AC and the aging grayscale AG are displayed on the test display panel. In an embodiment, after the aging color AC and the aging grayscale AG are displayed as much as the aging time AT on the test display panel, the observation color OC and the observation grayscale OG may be displayed on the test display panel, for example. In addition, the age data AD may be determined according to the observation luminance of each of the patterns PT1 to PT30 measured while the observation color OC and the observation grayscale OG are displayed on the test display panel.

In the illustrated embodiment, it is exemplified that the age data AD is periodically measured every ten aging time AT, but the age data AD of the disclosure is not necessarily measured periodically.

Referring to FIG. 6 and FIG. 7, the aging characteristics are labeled with the age data AD of the test display panels TP1 to TP3, and the artificial intelligence model may be trained with the aging characteristics labeled with the age data AD of the test display panels TP1 to TP3.

In an embodiment, the age data AD may be generated from a plurality of test display panels TP1 to TP3, for example. As the number of the test display panels TP1 to TP3 increases, data for training the artificial intelligence model may increase.

FIG. 7 illustrates the age data AD of the first test display panel TP1. Age data AD of the second test display panel TP2 and the third test display panel TP3 may also have a form as shown in FIG. 7.

In the illustrated embodiment, 3 test display panels TP1 to TP3 are illustrated, but the disclosure is not limited to the number of the test display panels TP1 to TP3.

The aging characteristics may be labeled with the age data AD of the test display panel. For better understanding and ease of description, FIG. 7 illustrates that the aging characteristics include the aging color AC, the aging grayscale AG, the initial aging luminance AL, the observation color OC, the observation grayscale OG, the initial observation luminance OL, the aging position AP (e.g., positions of the patterns PT1 to PT30), and the temperature T.

In an embodiment, at an aging time AT of 10, an aging characteristics including an aging color AC of white (W), an aging grayscale AG of 255 grayscales, an initial aging luminance AL of 120, an observation color OC of blue (B), an observation grayscale OG of 255 grayscales, an initial observation luminance OL of 80, an observation position AP of the first pattern PT1, and a temperature T of 30, may be labeled with age data AD of 0.94, for example. That is, the artificial intelligence model may be trained to have an output value of 0.94 when the aging characteristics including the aging time AT of 10, the aging color AC of white (W), the aging grayscale AG of 255 grayscales, the initial aging luminance AL of 120, the observation color OC of blue (B), the observation grayscale OG of 255 grayscales, the initial observation luminance OL of 80, the observation position AP of the first pattern PT1, and the temperature T of 30, is inputted.

In an embodiment, at the aging time AT of 10, an aging characteristics including an aging color AC of white (W), an aging grayscale AG of 255 grayscales, an initial aging luminance AL of 120, an observation color OC of blue (B), an observation grayscale OG of 128 grayscales, an initial observation luminance OL of 30, an observation position AP of the first pattern PT1, and a temperature T of 30, may be labeled with age data AD of 0.92, for example. That is, the artificial intelligence model may be trained to have an output value of 0.92 when the aging characteristics including the aging time AT of 10, the aging color AC of white (W), the aging grayscale AG of 255 grayscales, the initial aging luminance AL of 120, the observation color OC of blue (B), the observation grayscale OG of 128 grayscales, the initial observation luminance OL of 30, the observation position AP of the first pattern PT1, and the temperature T of 30, is inputted.

In an embodiment, at an aging time AT of 20, an aging characteristics including an aging color AC of white (W), an aging grayscale AG of 255 grayscales, an initial aging luminance AL of 120, an observation color OC of blue (B), an observation grayscale OG of 255 grayscales, an initial observation luminance OL of 80, an observation position AP of the first pattern PT1, and a temperature T of 30, may be labeled with age data AD of 0.91, for example. That is, the artificial intelligence model may be trained to have an output value of 0.91 when the aging characteristics including the aging time AT of 20, the aging color AC of white (W), the aging grayscale AG of 255 grayscales, the initial aging luminance AL of 120, the observation color OC of blue (B), the observation grayscale OG of 255 grayscales, the initial observation luminance OL of 80, the observation position AP of the first pattern PT1, and the temperature T of 30, is inputted.

In an embodiment, at the aging time AT of 20, an aging characteristics including an aging color AC of white (W), an aging grayscale AG of 255 grayscales, an initial aging luminance AL of 120, an observation color OC of blue (B), an observation grayscale OG of 128 grayscales, an initial observation luminance OL of 30, an observation position AP of the first pattern PT1, and a temperature T of 30, may be labeled with age data AD of 0.88, for example. That is, the artificial intelligence model may be trained to have an output value of 0.88 when the aging characteristics including the aging time AT of 20, the aging color AC of white (W), the aging grayscale AG of 255 grayscales, the initial aging luminance AL of 120, the observation color OC of blue (B), the observation grayscale OG of 128 grayscales, the initial observation luminance OL of 30, the observation position AP of the first pattern PT1, and the temperature T of 30, is inputted.

The artificial intelligence models may be trained with the labeled aging characteristics. In an embodiment, the trained artificial intelligence model may predict age data by receiving the aging characteristics, for example. In an embodiment, the artificial intelligence model may output virtual age data of a virtual display panel by receiving the aging characteristics, for example. The virtual age data may be age data predicted by the artificial intelligence model from arbitrary aging characteristics, and the virtual display panel may be a display panel corresponding to the age data predicted by the artificial intelligence model.

As described above, the artificial intelligence model may generate virtual age data of a virtual display panel when only aging characteristics of a new test display panel are measured. That is, the artificial intelligence model may generate the virtual age data of the virtual display panel corresponding to the new test display panel without measuring the age data AD of the new test display panel.

Therefore, in the inspecting method of the display panel of FIG. 1, the artificial intelligence model generates the virtual age data of the virtual display panel, so that the same effect as using a larger number of test display panels than the number of test display panels for which the age data AD is measured for actual age prediction may be obtained.

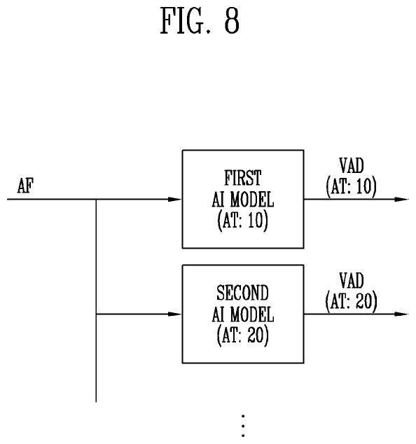

FIG. 8 illustrates a block diagram of an embodiment of an artificial intelligence model according to the inspecting method of the display panel of FIG. 1.

Referring to FIGS. 8, the inspecting method of the display panel of FIG. 1 may generate virtual age data VAD using artificial intelligence models according to the aging time AT.

In the embodiment, the artificial intelligence model may include a first artificial intelligence model according to a first aging time (e.g., 10) and a second artificial intelligence model according to a second aging time (e.g., 20) different from the first aging time.

In an embodiment, the first artificial intelligence model may generate virtual age data VAD for the first aging time (e.g., 10) by receiving an aging characteristic AF, for example. In an embodiment, the second artificial intelligence model may generate virtual age data VAD for the second aging time (e.g., 20) by receiving the aging characteristic AF, for example.

In an embodiment, the first artificial intelligence model may be trained with an aging characteristic in which age data at the first aging time (e.g., 10) is labeled, for example. In an embodiment, the second artificial intelligence model may be trained with an aging characteristic in which age data at the second aging time (e.g., 20) is labeled.

In the illustrated embodiment, two artificial intelligence models are exemplified, but the disclosure is not limited to the number of artificial intelligence models.

In the embodiment, the aging time AT and the aging characteristics may be labeled with the age data, and the artificial intelligence model may be trained with the labeled aging time AT and the aging characteristics. In this case, the artificial intelligence model may generate the virtual age data VAD by receiving the aging time AT and the aging characteristics.

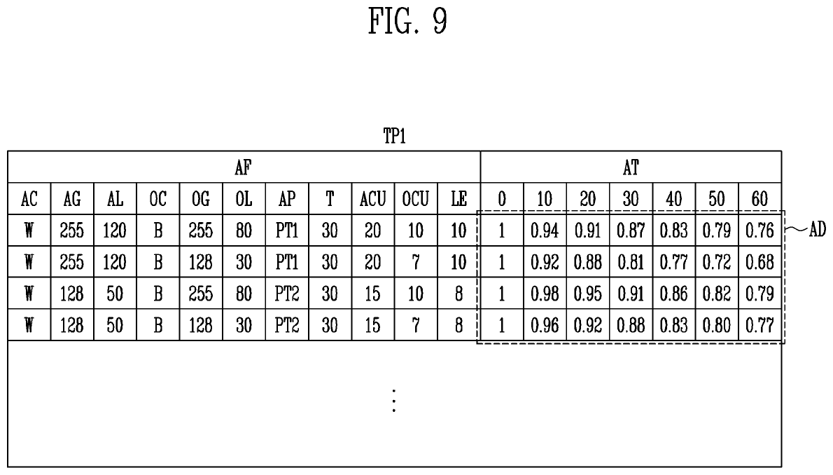

FIG. 9 illustrates an embodiment of age data of a first test display panel according to the inspecting method of the display panel according to the disclosure.

Since the inspecting method of the display panel in the illustrated embodiments is substantially the same as the inspecting method of the display panel of FIG. 1, except for the aging characteristics, the same reference numerals and reference symbols are used for the same or similar constituent elements, and redundant descriptions are omitted.

For better comprehension and ease of description, initial aging luminance AL, initial observation luminance OL, a temperature T, an aging time AT, an aging current ACU, an observation current OCU, and light efficiency LE in FIG. 9 represent relative values.

Referring to FIG. 2, FIG. 3, FIG. 6, and FIG. 9, the inspecting method of the display panel of FIG. 9 may display aging colors AC and aging grayscales AG on patterns PT1 to PT30 of test display panels TP1 to TP3, may measure initial aging luminance AL and aging currents ACU of the patterns PT1 to PT30, may display observation colors OC and observation grayscales OG on the test display panels TP1 to TP3, may measure initial observation luminance OL and observation currents OCU of the patterns PT1 to PT30, may measure temperatures T of the test display panels TP1 to TP3, may determine age data AD of the test display panels TP1 to TP3, may label aging characteristics with the age data AD of the test display panels TP1 to TP3, and may train an artificial intelligence model based on the aging characteristics labeled with the age data AD of the test display panels TP1 to TP3. The aging characteristics may include at least one of an aging color AC, an aging grayscale AG, an initial aging luminance AL, an observation color OC, an observation grayscale OG, an initial observation luminance OL, an aging position AP (e.g., positions of the patterns PT1 to PT30), a temperature T, an aging current ACU, an observation current OCU, and a light efficiency (also referred to as an optical efficiency) LE.

Here, the aging luminance and the observation luminance are measured with a luminance meter, the temperature T is measured with a temperature meter, the aging current ACU and the observation current OCU are measured with a current meter, and the temperature T may be the temperature of the test display panel. That is, even when the aging color AC, the aging grayscale AG, the observation color OC, the observation grayscale OG, and the aging position AP are the same, the initial aging luminance AL, the initial observation luminance OL, the temperature T, the aging current ACU, and the observation current OCU may be differently measured depending on the test display panel.

In the embodiment, the aging current ACU for training the artificial intelligence model may be a current applied to the test display panel measured by displaying the aging color AC and the aging grayscale AG on the test display panel before the test display panel is aged with the aging color AC and the aging grayscale AG. In another embodiment, the aging current ACU for training the artificial intelligence model may be a current applied to the test display panel measured by displaying the aging color AC and the aging grayscale AG on the test display panel after the test display panel is aged with the aging color AC and the aging grayscale AG for a predetermined time.

In the embodiment, the observation current OCU may be a current applied to the test display panel measured by displaying an observation image on the test display panel when the aging time AT of the test display panel is zero.

In another embodiment, the observation current OCU may be a current applied to the test display panel measured by displaying an observation image on the test display panel after the test display panel is aged with an aging image for a predetermined time. In this case, the aging time AT may be a time obtained by subtracting the predetermined time from the time when the aging image is displayed. That is, when the aging image is displayed for the predetermined time, the aging time AT may be zero.

In the embodiment, the aging current ACU and the observation current OCU may be a current applied to the entirety of the test display panel. In another embodiment, the aging current ACU and the observation current OCU may be a current applied to each of the patterns PT1 to PT30.

The light efficiency LE may be a ratio of luminance to a driving current of each sub-pixel SP. In an embodiment, when the currents flowing to the light-emitting elements of each sub-pixel SP are the same, the higher the light efficiency LE, the greater the luminance, for example.

The light efficiency LE may be different for each sub-pixel SP. The light efficiency LE for training the artificial intelligence model (that is, the light efficiency LE as an aging characteristic) may be measured for each of the patterns PT1 to PT30. In an embodiment, the light efficiency LE for training the artificial intelligence model may be determined based on the light efficiencies LE of the sub-pixels SP of each of the patterns PT1 to PT30, for example. In an embodiment, the light efficiency LE for training the artificial intelligence model may be an average of the light efficiencies LE of the sub-pixels SP of each of the patterns PT1 to PT30, for example.

In an embodiment, at an aging time AT of 10, an aging characteristic including an aging color AC of white (W), an aging grayscale AG of 255 grayscales, an initial aging luminance AL of 120, an observation color OC of blue (B), an observation grayscale OG of 255 grayscales, an initial observation luminance OL of 80, an observation position AP of the first pattern PT1, a temperature T of 30, an aging current ACU of 20, an observation current OCU of 10, and a light efficiency LE of the first pattern PT1 of 10, may be labeled with age data AD of 0.94, for example. That is, the artificial intelligence model may be trained to have an output value of 0.94 when the aging characteristic including the aging time AT of 10, the aging color AC of white (W), the aging grayscale AG of 255 grayscales, the initial aging luminance AL of 120, the observation color OC of blue (B), the observation grayscale OG of 255 grayscales, the initial observation luminance OL of 80, the observation position AP of the first pattern PT1, the temperature T of 30, the aging current ACU of 20, the observation current OCU of 10, and the light efficiency LE of 10, is inputted.

In an embodiment, at an aging time AT of 10, an aging characteristic including an aging color AC of white (W), an aging grayscale AG of 255 grayscales, an initial aging luminance AL of 120, an observation color OC of blue (B), an observation grayscale OG of 128 grayscales, an initial observation luminance OL of 30, an observation position AP of the first pattern PT1, a temperature T of 30, an aging current ACU of 20, an observation current OCU of 7, and a light efficiency LE of the first pattern PT1 of 10, may be labeled with age data AD of 0.92, for example. That is, the artificial intelligence model may be trained to have an output value of 0.92 when the aging characteristic including the aging time AT of 10, the aging color AC of white (W), the aging grayscale AG of 255 grayscales, the initial aging luminance AL of 120, the observation color OC of blue (B), the observation grayscale OG of 128 grayscales, the initial observation luminance OL of 30, the observation position AP of the first pattern PT1, the temperature T of 30, the aging current ACU of 20, the observation current OCU of 7, and the light efficiency LE of 10, is inputted.

In an embodiment, at an aging time AT of 20, an aging characteristic including an aging color AC of white (W), an aging grayscale AG of 255 grayscales, an initial aging luminance AL of 120, an observation color OC of blue (B), an observation grayscale OG of 255 grayscales, an initial observation luminance OL of 80, an observation position AP of the first pattern PT1, a temperature T of 30, an aging current ACU of 20, an observation current OCU of 10, and a light efficiency LE of the first pattern PT1 of 10, may be labeled with age data AD of 0.91, for example. That is, the artificial intelligence model may be trained to have an output value of 0.91 when the aging characteristic including the aging time AT of 20, the aging color AC of white (W), the aging grayscale AG of 255 grayscales, the initial aging luminance AL of 120, the observation color OC of blue (B), the observation grayscale OG of 255 grayscales, the initial observation luminance OL of 80, the observation position AP of the first pattern PT1, the temperature T of 30, the aging current ACU of 20, the observation current OCU of 10, and the light efficiency LE of 10, is inputted.

In an embodiment, at an aging time AT of 20, an aging characteristic including an aging color AC of white (W), an aging grayscale AG of 255 grayscales, an initial aging luminance AL of 120, an observation color OC of blue (B), an observation grayscale OG of 128 grayscales, an initial observation luminance OL of 30, an observation position AP of the first pattern PT1, a temperature T of 30, an aging current ACU of 20, an observation current OCU of 7, and a light efficiency LE of the first pattern PT1 of 10, may be labeled with age data AD of 0.88, for example. That is, the artificial intelligence model may be trained to have an output value of 0.88 when the aging characteristic including the aging time AT of 20, the aging color AC of white (W), the aging grayscale AG of 255 grayscales, the initial aging luminance AL of 120, the observation color OC of blue (B), the observation grayscale OG of 128 grayscales, the initial observation luminance OL of 30, the observation position AP of the first pattern PT1, the temperature T of 30, the aging current ACU of 20, the observation current OCU of 7, and the light efficiency LE of 10, is inputted.

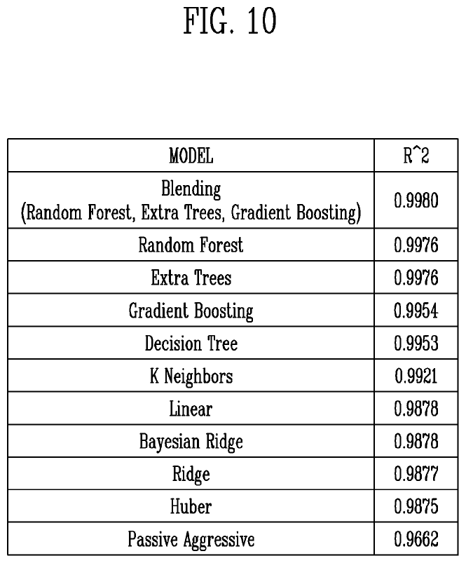

FIG. 10 illustrates a table of an embodiment of a coefficient of determination of an artificial intelligence model according to the inspecting method of the display panel of FIG. 1.

Referring to FIG. 10, the artificial intelligence model may be a regression model. In the embodiment, the artificial intelligence model may be one of a random forest regression model, an extra tree regression model, a gradient boosting regression model, a decision tree regression model, a K neighbors regression model, a linear regression model, a Bayesian Ridge regression model, a Ridge regression model, a Huber regression model, and a passive aggressive regression model.

The coefficient of determination is an index indicating a degree to which an independent variable explains a dependent variable in the regression model, and the higher the coefficient of determination, the higher the correlation between the independent variable and the dependent variable. That is, the higher the coefficient of determination, the higher the prediction accuracy of the artificial intelligence model. Here, the independent variable is an aging characteristic, and the dependent variable is age data.

In an embodiment, the coefficient of determination is a value of an explained sum of squares (“SSE”) divided by a total sum of squares (“SST”), for example. The SSE may be a total sum of squares of values obtained by subtracting an average of the age data (or an average of the virtual age data) from the virtual age data. The SST may be the total sum of squares of values obtained by subtracting an average of age data (or an average of the virtual age data) from the age data.

In an embodiment, the random forest regression model may have a coefficient of determination (R\hat{ }2) of 0.9976, for example. In an embodiment, the extra tree regression model may have a coefficient of determination (R\hat{ }2) of 0.9976, for example. In an embodiment, the gradient boosting regression model may have a coefficient of determination (R\hat{ }2) of 0.9954, for example. In an embodiment, the decision tree regression model may have a coefficient of determination (R\hat{ }2) of 0.9953, for example. In an embodiment, the K neighbors regression model may have a coefficient of determination (R\hat{ }2) of 0.9921, for example. In an embodiment, the linear regression model may have a coefficient of determination (R\hat{ }2) of 0.9878, for example. In an embodiment, the Bayesian Ridge regression model may have a coefficient of determination (R\hat{ }2) of 0.9878, for example. In an embodiment, the Ridge regression model may have a coefficient of determination (R\hat{ }2) of 0.9877, for example. In an embodiment, the Huber regression model may have a coefficient of determination (R\hat{ }2) of 0.9875, for example. In an embodiment, the passive aggressive regression model may have a coefficient of determination (R\hat{ }2) of 0.9662, for example.

In the embodiment, the artificial intelligence model may be generated by blending at least two regression models. In an embodiment, an artificial intelligence model may be generated by blending the random forest regression model, the extra tree regression model, and the gradient boosting regression model, for example. In an embodiment, the artificial intelligence model generated by blending the random forest regression model, the extra tree regression model, and the gradient boosting regression model may have a coefficient of determination (R\hat{ }2) of 0.9980, for example.

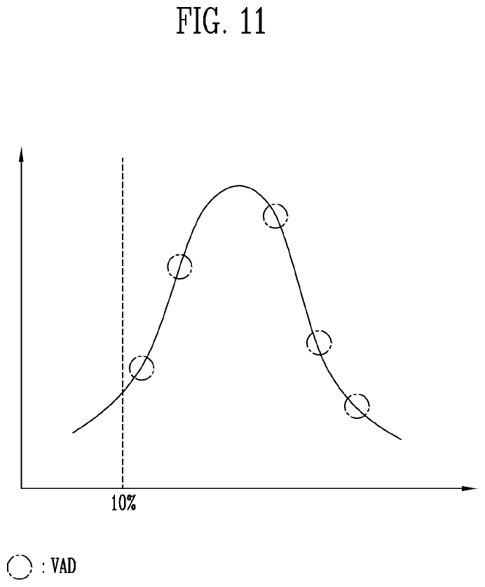

FIG. 11 illustrates a graph of an embodiment of normal distribution data according to the inspecting method of the display panel of FIG. 1.

FIG. 11 illustrates that five virtual age data VAD of the virtual display panel are generated from aging characteristics in five cases for convenience of explanation.

Referring to FIG. 11, the inspecting method of the display panel of FIG. 1 may normalize the virtual age data VAD to generate normal distribution data, and it may predict, based on data corresponding to a predetermined ratio of the normal distribution data, the age of the display panel.

In an embodiment, as shown in FIG. 11, the normal distribution data may be generated by normalizing the five virtual age data VAD of the virtual display panel, for example. In addition, since the worst case must be considered in predicting the age of the display panel, the age of the display panel may be predicted based on data corresponding to the lower 10% of the normal distribution data.

The virtual age data VAD of the virtual display panel may be generated by inputting aging characteristics measured from display panels (hereinafter referred to as additional display panels) other than the test display panel used for measuring the age data into the artificial intelligence model. That is, five additional display panels may be desired to generate the five virtual display panels.

The inspecting method of the display panel of FIG. 1 may generate the virtual age data VAD by measuring only the aging characteristics of the additional display panel without measuring the observation luminance other than the initial observation luminance of the additional display panel. In addition, since the aging characteristics of the additional display panel include values measured without aging the additional display panel (that is, values measured when the aging time is 0), increasing the number of additional display panels may be less restrictive than increasing the number of test display panels. Therefore, by increasing the additional display panels, the effect of increasing the number of display panels used for testing may be obtained, and accordingly, the accuracy of age prediction may be increased.

In the embodiment, the age of the display panel may be an aging time desired for a luminance retention rate to decrease to 50%. However, the age of the display panel only reflects the change in luminescence characteristics due to aging, and the disclosure is not limited to a method of defining the age of the display panel.

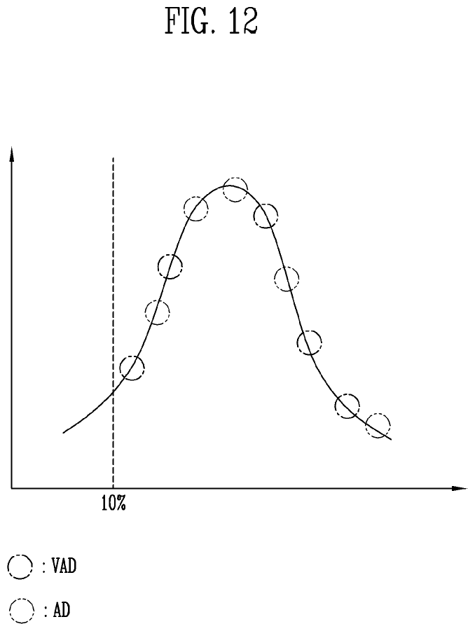

FIG. 12 illustrates a graph of an embodiment of normal distribution data according to an inspecting method of a display panel according to the disclosure.

Since the inspecting method of the display panel in the illustrated embodiment is substantially the same as the inspecting method of the display panel in FIG. 1, except for considering age data AD in predicting the age of the display panel, the same reference numerals and reference symbols are used for the same or similar constituent elements, and redundant descriptions are omitted.

FIG. 12 illustrates that from aging characteristics of five cases, five virtual age data VAD of the virtual display panel are generated and five age data AD of the test display panel are measured, for better comprehension and ease of description.

Referring to FIG. 12, the inspecting method of the display panel of FIG. 12 may normalize the virtual age data VAD and the age data AD of the test display panel to generate normal distribution data, and it may predict, based on data corresponding to a predetermined ratio of the normal distribution data, the age of the display panel.

In an embodiment, as shown in FIG. 12, the normal distribution data may be generated by normalizing the five virtual age data VAD of the virtual display panel and the five age data AD of the test display panel, for example. In addition, since the worst case must be considered in predicting the age of the display panel, the age of the display panel may be predicted based on data corresponding to the lower 10% of the normal distribution data.

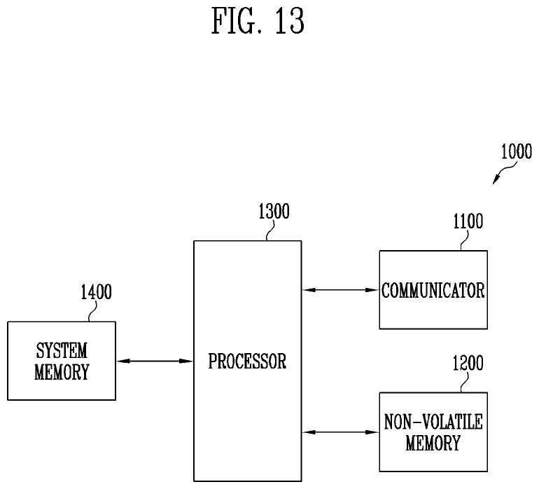

FIG. 13 illustrates a block diagram of an embodiment of an inspecting device according to the disclosure.

Referring to FIG. 13, the inspecting method of the display panel of FIG. 1 may be implemented through an inspecting device 1000. The inspecting device 1000 may include a communicator 1100, a non-volatile memory 1200, a processor 1300, and a system memory 1400.

In an embodiment, the inspecting device may be a computer device, for example.

The non-volatile memory 1200 may store the artificial intelligence model. The processor 1300 may predict the age of the display panel using the artificial intelligence model stored in the non- volatile memory 1200 (or an artificial intelligence model loaded into the system memory 1400).

The communicator 1100 may access a network through wired and/or wireless communication in response to control of the processor 1300.

The non-volatile memory 1200 may include at least one of storage media such as a flash memory, a hard disk, and a multimedia card that maintain stored data even when power is cut off. The non-volatile memory 1200 may write and read data in response to control of the processor 1300.

The processor 1300 may control operations of the communicator 1100, the non-volatile memory 1200, and the system memory 1400. The processor 1300 may perform various processes such as calculation and comparison by including a plurality of processing units (or a plurality of cores). In an embodiment, the processor 1300 may include a central processing unit (“CPU”), for example. In an embodiment, the processor 1300 may further include a graphics processing unit, for example.

The processor 1300 may load program codes and/or instruction words into the system memory 1400 and execute the loaded program codes and/or instruction words. In an embodiment, the processor 1300 may perform an operation for measuring the age of the display panel by loading the artificial intelligence model into the system memory 1400 and executing the loaded artificial intelligence model, for example.

In addition, the processor 1300 may load an operating system into the system memory 1400 and execute the loaded operating system to control overall operations of the inspecting device 1000.

The system memory 1400 may include at least one of a random access memory (“RAM”), a read only memory (“ROM”), and other types of computer readable storage media. In FIG. 13, the system memory 1400 is shown as a constituent element separate from the processor 1300, but this is only an example, and at least a portion of the system memory 1400 may be included in the processor 1300. The system memory 1400 may be divided into a plurality of constituent elements as desired.

In the embodiment, the inspecting device may include at least one of a luminance meter for measuring luminance, a thermometer for measuring temperature, and a current meter for measuring current. In another embodiment, the inspecting device may receive luminance data, temperature data, and current data from the outside.

The disclosure may be applied to a display device and an electronic device including the same. In an embodiment, the disclosure may be applied to a digital television (“TV”), a three dimensional (“3D”) TV, a mobile phone, a smart phone, a tablet computer, a VR device, a personal computer (“PC”), a home electronic device, a laptop computer, a personal digital assistance (“PDA”), a portable media player (“PMP”), a digital camera, a music player, a portable game console, a navigation, or the like, for example.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. An inspecting method of a display panel, the method comprising:
training an artificial intelligence model based on age data of a test display panel for an aging characteristic;
generating virtual age data of a virtual display panel from the aging characteristic using the artificial intelligence model; and
predicting an age of the display panel based on the virtual age data.

2. The inspecting method of the display panel of claim 1, wherein
the age data of the test display panel is a luminance retention rate according to an aging time of the test display panel.

3. The inspecting method of the display panel of claim 1, wherein
the artificial intelligence model includes a first artificial intelligence model according to a first aging time and a second artificial intelligence model according to a second aging time different from the first aging time.

4. The inspecting method of the display panel of claim 1, wherein
the aging characteristic includes at least one of an aging color, an aging grayscale, an initial aging luminance, an observation color, an observation grayscale, an initial observation luminance, an aging position, and a temperature.

5. The inspecting method of the display panel of claim 4, wherein
the training the artificial intelligence model includes:
displaying the aging color and the aging grayscale on a pattern of the test display panel;
measuring the initial aging luminance of the pattern;
displaying the observation color and the observation grayscale on the test display panel;
measuring the initial observation luminance of the pattern;
measuring the temperature of the test display panel;
determining the age data of the test display panel;
labeling the aging characteristic with the age data of the test display panel; and
training the artificial intelligence model with the aging characteristic labeled with the age data of the test display panel.

6. The inspecting method of the display panel of claim 5, wherein
the age data of the test display panel is measured by displaying the observation color and the observation grayscale on the test display panel.

7. The inspecting method of the display panel of claim 5, wherein
the age data of the test display panel is measured according to an aging time for which the aging color and the aging grayscale are displayed.

8. The inspecting method of the display panel of claim 1, wherein
the aging characteristic includes at least one of an aging color, an aging grayscale, an initial aging luminance, an observation color, an observation grayscale, an initial observation luminance, an aging position, a temperature, an aging current, an observation current, and a light efficiency.

9. The inspecting method of the display panel of claim 8, wherein
the training the artificial intelligence model includes:
displaying the aging color and the aging grayscale on a pattern of the test display panel;
measuring the initial aging luminance and the aging current of the pattern;
displaying the observation color and the observation grayscale on the test display panel;
measuring the initial observation luminance and the observation current of the pattern;
measuring the temperature of the test display panel;
determining the age data of the test display panel;
labeling the aging characteristic with the age data of the test display panel; and
training the artificial intelligence model with the aging characteristic labeled with the age data of the test display panel.

10. The inspecting method of the display panel of claim 1, wherein
the artificial intelligence model is a regression model.

11. The inspecting method of the display panel of claim 1, wherein
the artificial intelligence model is one of a random forest regression model, an extra tree regression model, and a gradient boosting regression model.

12. The inspecting method of the display panel of claim 1, wherein
the artificial intelligence model is generated by blending at least two regression models.

13. The inspecting method of the display panel of claim 1, wherein
the predicting the age of the display panel includes:
normalizing the virtual age data and generating normal distribution data; and
predicting the age of the display panel based on data corresponding to a predetermined ratio of the normal distribution data.

14. The inspecting method of the display panel of claim 1, wherein
the predicting the age of the display panel includes:
normalizing the virtual age data and the age data of the test display panel and generating normal distribution data; and
predicting the age of the display panel based on data corresponding to a predetermined ratio of the normal distribution data.

15. An inspecting device comprising:
a memory which stores an artificial intelligence model; and
a processor which predicts an age of a display panel by the artificial intelligence model stored in the memory;
wherein the processor generates virtual age data of a virtual display panel from an aging characteristic by the artificial intelligence model and predicts the age of the display panel based on the virtual age data, and
the artificial intelligence model is trained based on age data of a test display panel for the aging characteristic.

16. The inspecting device of claim 15, wherein
the artificial intelligence model includes:
a first artificial intelligence model according to a first aging time; and
a second artificial intelligence model according to a second aging time different from the first aging time.

17. The inspecting device of claim 15, wherein
the aging characteristic includes at least one of an aging color, an aging grayscale, an initial aging luminance, an observation color, an observation grayscale, an initial observation luminance, and a temperature.

18. The inspecting device of claim 15, wherein
the aging characteristic includes at least one of an aging color, an aging grayscale, an initial aging luminance, an observation color, an observation grayscale, an initial observation luminance, a temperature, an aging current, an observation current, and a light efficiency.

19. The inspecting device of claim 15, wherein
the artificial intelligence model is a regression model.

20. The inspecting device of claim 15, wherein
the artificial intelligence model is generated by blending at least two regression models.
